(19) United States
(12) Patent Application Publication
(10) Pub. No.: US 2012/0168823 A1
(43) Pub. Date: Jul. 5, 2012

(54) SEMICONDUCTOR DEVICE AND METHOD FOR MANUFACTURING THE SAME

(76) Inventors: Zhijiong Luo, Poughkeepsie, NY (US); Haizhou Yin, Poughkeepsie, NY (US); Huilong Zhu, Poughkeepsie, NY (US)

(21) Appl. No.: 13/377,766

(22) PCT Filed: Apr. 25, 2011
(86) PCT No.: PCT/CN2011/073257

§ 371 Date: Dec. 12, 2011

(30) Foreign Application Priority Data
Dec. 31, 2010 (CN) 201010617447.5

(51) Int. Cl. H01L 29/26; H01L 21/66

(52) U.S. Cl. 257/200; 438/5; 257/E29.081; 257/E21.53

(57) ABSTRACT

The present application discloses a semiconductor device and a method for forming the same. The method comprises: providing a first semiconductor layer and forming a first STI in the first semiconductor layer; determining a selected region in the first semiconductor layer, and making a portion of the first semiconductor layer in the selected region recessed; and in the selected region, epitaxially growing a second semiconductor layer on the first semiconductor layer, wherein the material of the second semiconductor layer is different from that of the first semiconductor layer. According to the present invention, a structure with a second semiconductor layer selectively epitaxially grown and embedded in the first semiconductor layer can be formed by a simple process, and defects generated during the epitaxial growth process can be further reduced.

The present application claims priority to a Chinese patent application No. 201010617447.5, filed on Dec. 31, 2010 and entitled “semiconductor device and method for manufacturing the same”, the entire disclosure of which is incorporated herein by reference.

### TECHNICAL FIELD

The invention relates to the semiconductor field, and particularly, to a semiconductor device comprising a heteroepitaxial structure and a method for manufacturing the same.

### BACKGROUND

Generally, heteroepitaxy means epitaxially growing a crystal material on another crystal material, for example, epitaxially growing germanium (Ge) or III-V group compound semiconductor, etc. on a silicon (Si) substrate. With the continuous development of the semiconductor technology, the heteroepitaxy technology is becoming more and more important. For example, a high-performance Ge-channel metal oxide semiconductor field effect transistor (MOSFET) can be formed by depositing Ge, which has high carrier mobility, as a channel material on a Si substrate. Further, it is possible to facilitate the integration of optoelectronic devices with the Si complementary metal oxide semiconductor (CMOS) technology by, for example, depositing a III-V group compound semiconductor material or the like on a Si substrate.

However, the lattices of two crystal materials generally do not match, causing defects such as dislocations during the growth. For example, epitaxially growing more than a few nanometers (nm) of Ge directly on Si can lead to a dislocation density of 10⁸-10⁹/cm² due to the lattice mismatch of 4.2% between the two materials. The dislocations have negative impacts on the grown crystal material and the resulting device.

Currently, various methods have been proposed to reduce such defects generated in heteroepitaxial growth, e.g. the graded buffer technology, the post-growth high-temperature annealing technology, the aspect ratio trapping (ART) technology, etc. FIG. 1 is a schematic diagram showing how to reduce the defects by ART. As shown in FIG. 1, a dielectric material (e.g. SiO₂) 110 is disposed on a Si substrate 100. The dielectric material 110 has openings with a large aspect ratio (AR) defined therein. Then, a Ge layer 120, for example, is epitaxially grown on the Si substrate 100. It has been found that defects such as dislocations generated during the growth are approximately perpendicular to the growing surface. Since the size of the openings defined in the dielectric material 110 is relatively small, the grown Ge material in the respective openings generally has a profile where the middle portion is relative higher and side portions are relative lower. Namely, the growing surface is not parallel to the substrate surface, so the defects 130 extend upward in oblique directions as shown in FIG. 1. Finally, these defects terminate at the non-crystal dielectric material 110 and are prevented from further extending upward. On the other hand, when the semiconductor materials which are epitaxially grown in adjacent openings converge above the dielectric material 110, coalescence dislocations 140 will occur.

Further, when it is desired to selectively epitaxially grow Ge on a Si substrate 100, namely, the selectively epitaxially grown Ge material is surrounded, for example, by Si material, two epitaxial processes are necessary. Firstly, as described above, the dielectric material 110 is formed on the Si substrate 100, and the Ge layer 120 is epitaxially grown. Then, the Ge layer 120 is selectively localized and the Si material is further epitaxially grown on the exposed surface of Si substrate 100, so as to form a structure where the selectively epitaxially grown Ge layer is embedded in the Si layer.

In view of the above, it is necessary to provide a new semiconductor structure and a method to help the formation of a selectively epitaxially grown layer and to further reduce defects in the epitaxially grown material.

### SUMMARY

An objective of the present invention is to provide a semiconductor structure and a method for manufacturing the same, which effectively reduce defects caused by heteroepitaxy and are very advantageous in forming a selectively epitaxially grown epitaxial layer.

According to an aspect of the present invention, there is provided a method for manufacturing a semiconductor device, comprising: providing a first semiconductor layer and forming a first shallow trench isolation (STI) in the first semiconductor layer; determining a selected region in the first semiconductor layer, and making a portion of the first semiconductor layer in the selected region recessed; and in the selected region, epitaxially growing a second semiconductor layer on the first semiconductor layer, wherein the material of the second semiconductor layer is different from that the material of the first semiconductor layer.

According to an embodiment of the present invention, a structure where the second semiconductor layer which is selectively epitaxially grown is embedded in the first semiconductor layer can be formed by one epitaxy process. Therefore, the manufacturing process can be significantly simplified.

Optionally, after forming the second semiconductor layer, the method may further comprise forming a second STI in the second semiconductor layer such that the first STI is connected with the second STI, and the first STI and the second STI overlap at an interface between the first STI and the second STI.

Advantageously, coalescence dislocations formed during epitaxial growth can be further reduced by forming the second STI in the epitaxial second semiconductor layer.

Optionally, the step of determining the selected region in the first semiconductor layer and making the first semiconductor layer in the selected region recessed may comprise: forming a mask layer on the first semiconductor layer; patterning the mask layer to expose the selected region; and removing the portion of the first semiconductor layer of a certain thickness exposed in the selected region.

According to an embodiment of the present invention, in the selected region, since the first semiconductor layer is recessed, the STI formed in the first semiconductor layer can effectively ART the growth defects during the epitaxial growth.

Optionally, if there are dislocations in a portion of the second semiconductor layer adjacent to the first semiconductor layer, the dislocations all terminate at the first STI remained after the portion of first semiconductor layer of the certain thickness is removed. This helps to remove the dislocations in the portion of the second semiconductor layer distant from the first semiconductor layer.

Optionally, after epitaxially growing the second semiconductor layer and before forming the second STI, or after forming the second STI, the method may further comprise performing planarization such that the first semiconductor layer and the second semiconductor layer form a continuous plane.

Optionally, the material of the first semiconductor layer may comprise Si, and the material of the second semiconductor layer may comprise Ge or III-V group compound semiconductor.

According to a further aspect of the present invention, there is provided a semiconductor device, comprising: a first semiconductor layer; a first shallow trench isolation (STI) formed in the first semiconductor layer, wherein a portion of the first semiconductor layer is recessed in a selected region; and a second semiconductor layer on the portion of the first semiconductor layer in the selected region, wherein the material of the second semiconductor layer is different from the material of the first semiconductor layer.

Optionally, the semiconductor device may further comprise a second STI connected with the first STI, wherein the first STI and the second STI overlap at an interface between the first STI and the second STI. This helps to remove the coalescence dislocations in the second semiconductor layer.

Optionally, there are dislocations in a portion of the second semiconductor layer adjacent to the first semiconductor layer, and at least one of the dislocations terminates at a sidewall of the first STI. This helps to reduce the dislocations in the portion of the second semiconductor layer distant from the first semiconductor layer.

Optionally, the first semiconductor layer and the second semiconductor layer may form a continuous plane.

Optionally, the material of the first semiconductor layer may comprise Si, and the material of the second semiconductor layer may comprise Ge or III-V group compound semiconductor.

The semiconductor device according to the present invention can also achieve the characteristics and advantages of the above method according to the present invention.

### BRIEF DESCRIPTION OF THE DRAWINGS

The above and other objectives, features, and advantages of the present invention will become apparent from the following descriptions on embodiments of the present invention with reference to the drawings, in which:

FIG. 1 is a diagram showing a structure formed by a conventional heteroepitaxial growth method; and

FIGS. 2-7 are schematic cross-sectional views showing structures obtained in respective stages of a process flow for manufacturing a semiconductor structure according to an embodiment of the present invention.

### DETAILED DESCRIPTION OF EMBODIMENTS

Next, the present invention will be described with reference to specific embodiments shown in the drawings. However, it should be understood that these descriptions are only exemplary and are not intended to limit the scope of the present invention. Further, in the following, explanations on well-known structures and technologies are omitted, in order not to unnecessarily obscure the concept of the present invention.

In the drawings, various layer structures according to embodiments of the present invention are schematically shown. However, they are not drawn to scale, and some features may be enlarged while some features may be omitted for purpose of clarity. Shapes, sizes and relative positions of respective regions and layers are only exemplary, and deviations therefrom may occur due to manufacture tolerances and technical limits. Those skilled in the art can otherwise design regions/layers of different shapes, sizes, or relative positions according to actual requirements.

As shown in FIG. 2, firstly, a semiconductor substrate 200 is provided. The semiconductor substrate 200 may comprise a first semiconductor material, e.g. Si or Ge, etc. In the following descriptions, the present invention will be described by taking a Si substrate as an example. However, it does not mean that the present invention is limited thereto. Pre-patterned shallow trench isolations (STIs) 210 are formed in the semiconductor substrate 200. For example, the material of the STIs 210 comprises silicon oxide. Those skilled in the art can devise various ways to form the STI, and detailed descriptions thereof are omitted. In another embodiment, the first semiconductor material (or a first semiconductor layer) may comprise silicon-on-insulator (SOI) or silicon-germanium-on-insulator, or any semiconductor material such as SiC formed on the semiconductor substrate 200. Also, the first semiconductor material may comprise any semiconductor material formed on other types of substrate (e.g. a glass substrate), or even III-V group compound semiconductor (e.g. GaAs, InP, etc.) or II-VI group compound semiconductor (e.g. ZnSe, ZnS), etc.

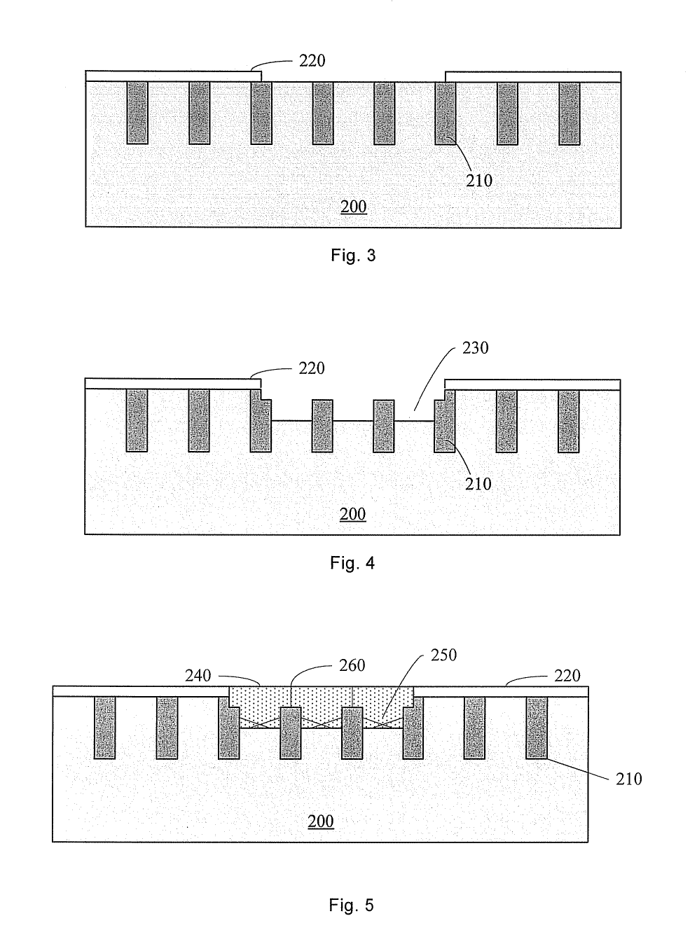

Then, as shown in FIG. 3, a selectively epitaxial growth region is defined on the semiconductor substrate 200. Particularly, for example, a mask layer 220 (e.g. silicon nitride) may be formed on the semiconductor substrate 200 and then be patterned, such that the mask layer 220 exposes a region of the semiconductor substrate, which is to be used for the epitaxial growth, and covers other regions of the semiconductor substrate that are not to be used for the epitaxial growth. Those skilled in the art can devise various ways to define the epitaxial growth region other than the above-described manner using the mask layer.

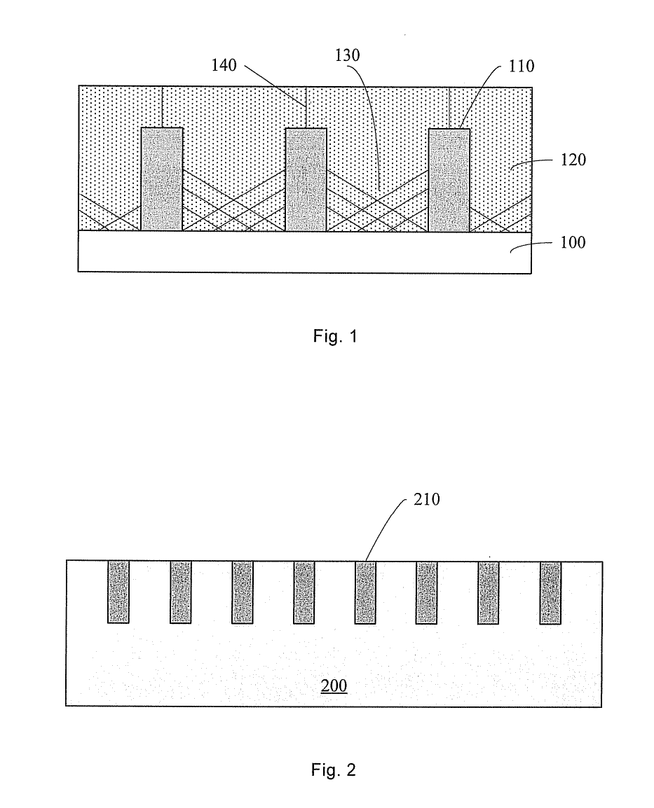

Next, as shown in FIG. 4, in the epitaxial growth region, the semiconductor substrate 200 is recessed. For example, a portion of the semiconductor substrate 200 of a certain thickness may be removed by etching the semiconductor substrate 200 (e.g. Si) selectively to the STIs 210 (e.g. silicon oxide) or by reactive ion etching (RIE), etc., such that the semiconductor substrate 200 is recessed. FIG. 4 also shows that a portion (which is very small or otherwise is negligible) of the STI 210 may also be removed due to the etching. Therefore, the STI 210 is still protruded with respect to the semiconductor substrate 200. Namely, the STI 210 defines a plurality of openings so that in the subsequent epitaxial growth process, defects can be trapped as in the ART technology (referring to FIG. 1).

Then, as shown in FIG. 5, in the epitaxial growth region, a second semiconductor material 240 (or a second semiconductor layer), e.g. Ge, which is different from the first semiconductor material, is epitaxially grown on the exposed surface of the semiconductor substrate 200. Of course, the second semiconductor material is not limited to Ge, and may also comprise IV group compound semiconductor (e.g. SiGe, SiC, etc.), III-V group compound semiconductor (e.g. GeAs, InP, etc.), or II-VI group compound semiconductor (e.g. ZnSe, ZnS, etc.), or the like. Generally, there is a lattice mismatch (resulting in dislocations, for example) between the second semiconductor material and the first semiconductor material. The dislocations all terminate at the first STIs remained after the first semiconductor material of a certain thickness is removed. This helps to trap the defects (e.g. the dislocations) generated during the epitaxial growth with the pre-patterned STIs (i.e. the first STI), and further helps to eliminate the dislocations in the portion of the second semiconductor layer distant from the first semiconductor layer. The specific positions of the dislocations may be detected by process detection. Otherwise, according to the prior art, the semiconductor substrate may be sufficiently recessed, so that, for example, the aspect ratio of the resulting openings 230 (only the openings between the adjacent remained first STIs) is larger than or equal to 1.

The second semiconductor material may be epitaxially grown in various ways, e.g. by metal organic chemical vapor deposition (MOCVD), low pressure chemical vapor deposition (LPCVD), molecular beam epitaxy (MBE), and atom layer deposition (ALD). The epitaxial growth process is known and thus detailed descriptions thereof are omitted.

As described above, the epitaxial growth will cause various defects, such as the dislocations 250 trapped in the bottom of the openings and coalescence dislocations 260 between adjacent openings. The coalescence dislocations 260 extend upward in the body of the grown second semiconductor material 240, and thus will affect the performance of a resulting device to some extent. Since the coalescence dislocations 260 are formed by the semiconductor materials which are epitaxially grown respectively in adjacent openings converging with each other, each of the coalescence is substantially positioned above the STI 210 between the adjacent openings.

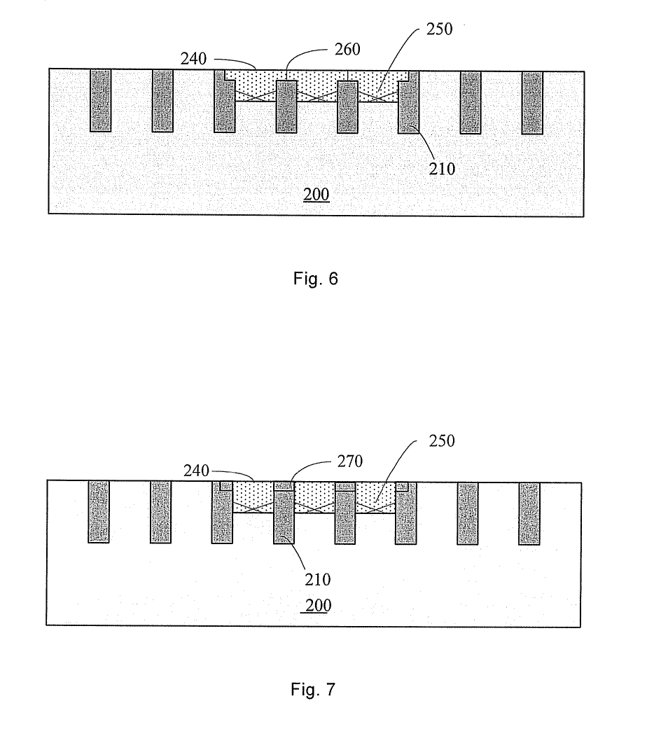

Next, as shown in FIG. 6, the first semiconductor layer and the second semiconductor layer form a continuous plane (which means that the height difference between any two points in the plane is within a range allowed by a process tolerance), for example, by a planarization process such as chemical mechanical planarization (CMP). During the planarization, the mask layer 220 is also removed. Thus, a structure in which the selectively grown second material 240 is epitaxially grown at a desired position (which is defined by the mask layer 220 as described above, for example) on the semiconductor substrate 200 is obtained.

Then, optionally, as shown in FIG. 7, an STI process is performed again. Particularly, the STI process is performed in the epitaxial growth region and in the grown second semiconductor material 240 to form STIs 270 at positions corresponding to the pre-patterned STIs 210, such that the second STIs 270 and the respective first STIs 210 are connected with each other. For example, at an interface between the first STI 210 and the second STI 270, the first STI 210 and the second STI 270 overlap. Herein, the term “overlap” means that the distance between the borders of the STIs is within a range allowed by a process tolerance. It can be seen that the formation of the STIs 270 is able to not only achieve the isolation but also remove the coalescence dislocations 260 generated in the epitaxial growth.

In the above description, the planarization is performed (referring to FIG. 6) before the STIs 270 are formed (referring to FIG. 7, wherein after the above-described process, the first semiconductor layer and the second semiconductor layer are separated by the first STIs 210), those skilled in the art should understand that the planarization shown in FIG. 6 may otherwise be performed after forming the STIs 270. After this process, the first semiconductor layer and the second semiconductor layer are separated by the second STIs 270, or the first semiconductor layer and the second semiconductor layer are separated by the first STIs 210 and the second STIs 270. Further, if the mask layer 220 comprises nitride or the like, it is also possible not to remove the mask layer 220. Furthermore, in other embodiments, the second STIs 270 may be patterned in a different way from the first STIs 210 according to process requirements, and the second STIs 270 may even be unconnected with the first STIs 210.

Thus, a semiconductor structure according to an embodiment of the present invention is obtained. As shown in FIG. 7, the semiconductor structure comprises: a first semiconductor layer 200; a first STI (210) formed in the semiconductor substrate 200, wherein the first semiconductor layer is recessed in a selected epitaxial growth region; and a second semiconductor layer 240 epitaxially grown on the first semiconductor layer in the selected epitaxial growth region.

Optionally, the semiconductor structure may further comprise: a second STI 270 connected with the first STI 210, wherein at the interface between the first STI 210 and the STI 270, the first STI 210 and the second STI 270 overlap. This helps to remove the coalescence dislocations in the second semiconductor layer 240. Optionally, the first semiconductor layer and the second semiconductor layer may form a continuous plane.

It can be seen that the defects 250 (e.g. dislocations) generated during the epitaxial growth remain at the bottom of the second semiconductor layer 240. Namely, the dislocations exist in a portion of the second semiconductor layer adjacent to the first semiconductor layer. At least one of the dislocations terminates at a sidewall of the first STI. This helps to reduce the dislocations in a portion of the second semiconductor layer distant from the first semiconductor layer. The coalescence dislocations tending to extend upward are removed by the STI process. Additionally, the method according to the present invention may be well combined with the formation of STIs to prevent the processes from being complicated.

Further, according to the embodiment of the present invention, the structure with a selectively epitaxially grown layer (240) embedded in the first semiconductor layer (the semiconductor substrate 200) is formed by one epitaxial growth process. However, according to the method in the prior art, two epitaxial growth processes are required to form the structure shown in FIG. 7.

The structural compositions, materials, and forming methods of the respective parts in the respective embodiments of the semiconductor structure may be the same as those described in the above-described method embodiments for forming the semiconductor structure, and thus detailed descriptions thereof are omitted.

In the above description, details of patterning and etching of the respective layers are not provided. It is to be understood by those skilled in the art that various means in the prior art may be utilized to form the layers and regions in desired shapes. Further, to achieve the same feature, those skilled can devise different methods than those described above. Although the respective embodiments are described respectively above, it does not necessarily mean that advantageous features of those embodiments cannot be used in combination.

The present invention is described above with reference to the embodiments thereof. However, those embodiments are provided just for illustrative purpose, rather than limiting the present invention. The scope of the invention is defined by the attached claims as well as equivalents thereof. Those skilled in the art can make various alternations and modifications without departing from the scope of the invention, which all fall into the scope of the invention.

1. A method for manufacturing a semiconductor device, comprising:
providing a first semiconductor layer and forming a first shallow trench isolation (STI) in the first semiconductor layer;
determining a selected region in the first semiconductor layer, and making a portion of the first semiconductor layer in the selected region recessed; and
in the selected region, epitaxially growing a second semiconductor layer on the first semiconductor layer, wherein the material of the second semiconductor layer is different from the material of the first semiconductor layer.

2. The method according to claim 1, wherein, after forming the second semiconductor layer, the method further comprises: forming a second STI in the second semiconductor layer such that the first STI is connected with the second STI, and the first STI and the second STI overlap at an interface between the first STI and the second STI.

3. The method according to claim 1, wherein the step of determining the selected region in the first semiconductor layer and making the first semiconductor layer in the selected region recessed comprises:
forming a mask layer on the first semiconductor layer;
patterning the mask layer to expose the selected region; and
removing the portion of the first semiconductor layer of a certain thickness exposed in the selected region.

4. The method according to claim 3, wherein, if there are dislocations in a portion of the second semiconductor layer adjacent to the first semiconductor layer, the dislocations all terminate at the first STI remained after the portion of first semiconductor layer of the certain thickness is removed.

5. The method according to claim 3, wherein, after epitaxially growing the second semiconductor layer and before forming the second STI, or after forming the second STI, the method further comprises:
performing planarization such that the first semiconductor layer and the second semiconductor layer form a continuous plane.

6. The method according to claim 1, wherein the material of the first semiconductor layer comprises Si, and the material of the second semiconductor layer comprises Ge or III-V group compound semiconductor.

7. A semiconductor device, comprising:
a first semiconductor layer;
a first shallow trench isolation (STI) formed in the first semiconductor layer, wherein a portion of the first semiconductor layer is recessed in a selected region; and
a second semiconductor layer on the portion of the first semiconductor layer in the selected region, wherein the material of the second semiconductor layer is different from the material of the first semiconductor layer.

8. The semiconductor device according to claim 7, wherein the semiconductor device further comprises a second STI connected with the first STI, wherein the first STI and the second STI overlap at an interface between the first STI and the second STI.

9. The semiconductor device according to claim 7, wherein there are dislocations in a portion of the second semiconductor layer adjacent to the first semiconductor layer, and at least one of the dislocations terminates at a sidewall of the first STI.

10. The semiconductor device according to claim 8, wherein the first semiconductor layer and the second semiconductor layer form a continuous plane.

11. The semiconductor device according to claim 7, wherein the material of the first semiconductor layer comprises Si, and the material of the second semiconductor layer comprises Ge or III-V group compound semiconductor.

12. The method according to claim 2, wherein the step of determining the selected region in the first semiconductor layer and making the first semiconductor layer in the selected region recessed comprises:
forming a mask layer on the first semiconductor layer;
patterning the mask layer to expose the selected region; and
removing the portion of the first semiconductor layer of a certain thickness exposed in the selected region.
